(19) United States
(12) Patent Application Publication
(10) Pub. No.: US 2026/0082501 A1
(43) Pub. Date: Mar. 19, 2026

(54) RELEASE MECHANISM FOR COLD SWAP DEVICES

(71) Applicant: DELL PRODUCTS L.P., Round Rock, TX (US)

(72) Inventors: John Donachy, Austin, TX (US); Sean O’Donnell, Poughkeepsie, NY (US); Eduardo Escamilla, Round Rock, TX (US); Nicholas Poteracki, Austin, TX (US); Corbett Schoenfelt, Austin, TX (US)

(21) Appl. No.: 18/888,751

(22) Filed: Sep. 18, 2024

(51) Int. Cl. H05K 7/14

(52) U.S. Cl. CPC H05K 7/1402; H05K 7/1487

(57) ABSTRACT

A drive carrier for a cold plug device of an information handling system includes a front portion to be placed in physical communication with the device. The front portion includes a handle and first and second latches. The handle is rotatable between a locked position and an unlocked position. The first latch is configured to slide between first and second positions, and the handle is held in the locked position when the first latch is in the first position. The second latch is configured to slide between a third position and a fourth position. A first end of the second latch is in physical communication with a portion of the first latch when the second latch is in the third position. The handle transitions from the locked position to the unlocked position when the first latch is in the second position and the second latch is in the fourth position.

### FIELD OF THE DISCLOSURE

The present disclosure generally relates to information handling systems, and more particularly relates to a release mechanism for cold swap devices.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A drive carrier for a cold plug device of an information handling system includes a front portion to be placed in physical communication with the device. The front portion includes a handle and first and second latches. The handle may be rotatable between a locked position and an unlocked position. The first latch may slide between a first position and a second position, and the handle may be held in the locked position when the first latch is in the first position. The second latch may slide between a third position and a fourth position. A first end of the second latch is in physical communication with a portion of the first latch when the second latch is in the third position. The handle may transition from the locked position to the unlocked position when both the first latch is in the second position and the second latch is in the fourth position.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system including multiple cold and hot plug devices according to at least one embodiment of the present disclosure;

FIG. 2 is a diagram of a 1T device carrier according to at least one embodiment of the present disclosure;

FIG. 3 is a diagram of a 2T device carrier according to at least one embodiment of the present disclosure;

FIG. 4 is a cross-sectional view of a device carrier according to at least one embodiment of the present disclosure;

FIGS. 5-7 are diagrams of different components of a device carrier in different positions during a transition from a locked position to an unlocked position according to at least one embodiment of the present disclosure; and

FIG. 8 is a block diagram of a general information handling system according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

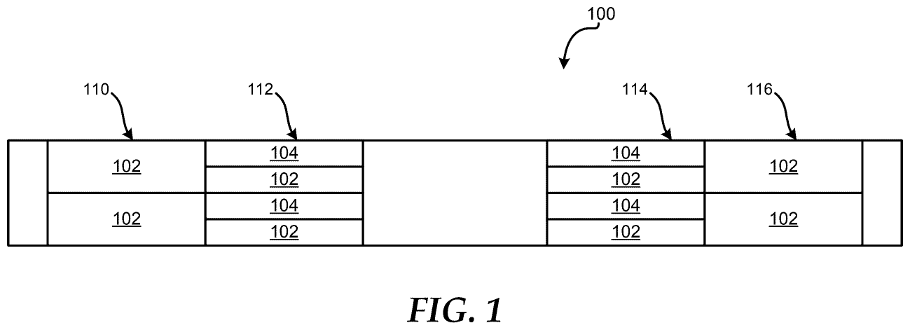

FIG. 1 illustrates an information handling system 100 according to at least one embodiment of the present disclosure. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various other I/O devices, such as a keyboard, a mouse, and a video display. The information handling system may also include one or more busses operable to transmit communications between the various hardware components.

FIG. 1 illustrates an information handling system or server 100 to receive multiple cold plug devices 102 and hot plug devices 104 according to at least one embodiment of the disclosure. Server 100 includes multiple bays 110, 112, 114, and 116 to receive cold plug devices 102 and hot plug devices 104. Each bay 110-116 may individually receive devices of a single type of media, such as only cold plug devices 102 or only hot plug devices 104, or may receive devices of different types of media, such as both cold plug devices 102 and hot plug devices 104. In certain examples, cold plug devices 102 may be any suitable device that requires server 100 to be powered down before the device is added to or removed from the server. Hot plug devices 104 may be any suitable device that may be added to or removed from server 100 while the server is running without causing a significant interruption to the operations being performed in the server. In an example, server 100 may be configured to utilize any suitable types of media devices 102 and 104. For example, devices 102 and 104 may include, but are not limited to, non-volatile memory express (NVMe), dynamic random access memory (DRAM) expansion, storage class memory, and network interface cards. In an example, server 100 may include a backplane with a common connector to interface with devices of different technologies.

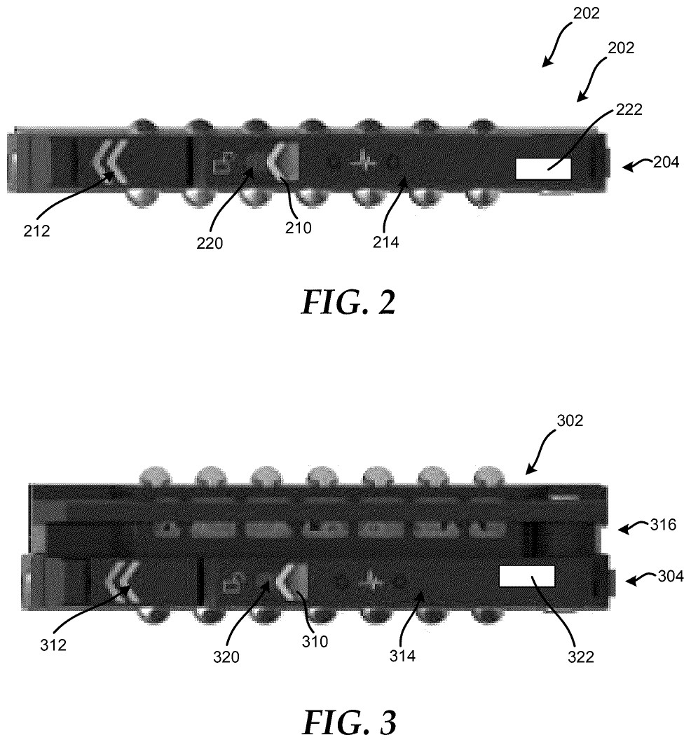

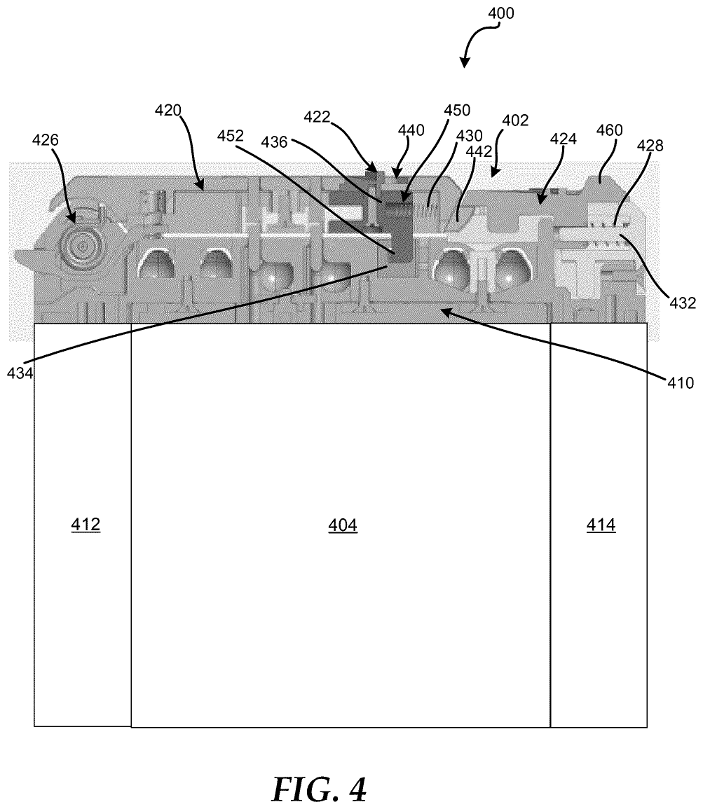

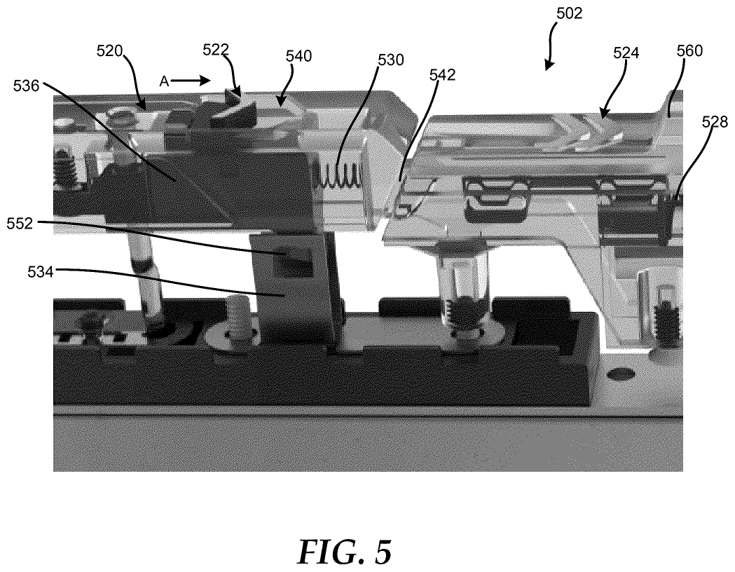

Based on the common connector of the backplane, server 100 may include a mix of device types, such as cold plug devices 102 and hot plug devices 104. In an example, hot plug devices 104 may be inserted or removed from the backplane of server 100 while the server is powered on or off. However, cold plug devices 102 only may be safely inserted or removed from the backplane of server 100 when the server is powered off. In certain examples, an information handling system, such as server 100, may be commonly populated with hot plug devices 104, such as hot plug NVMe devices. In these situations, an individual associated with server 100 may frequently remove hot plug devices 104, such that the individual may mistakenly remove a cold plug device 102 without first powering down the server. If a user removes a cold plug device 102 without shutting down server 100, the removal of the cold plug device may result in data loss, unplanned system downtime/failure, or other unsatisfactory results. An information handling system, such as server 100 or device 102, may be improved by drive carrier 202 of FIG. 2, drive carrier 302 of FIG. 3, drive carrier 402 of FIG. 4, and drive carrier 502 of FIGS. 5-7. For example, drive carriers 202, 302, 402, and 502 may have multiple latches to be unlocked before the drive carrier and corresponding device may be removed from an information handling system, such as server 100.

FIG. 2 illustrates drive carrier 202 according to at least one embodiment of the disclosure. Device carrier 202 includes a front portion 204, which in turn includes a primary latch 210, a secondary latch 212, and a handle 214. Handle 214 may be any suitable component such as a cam lever, which may be utilized during removal of a device from an information handling system, such as cold plug device 102 in server 100 of FIG. 1. Handle 214 includes a latch channel 220 and a label 222. Drive carrier 202 may include additional components without varying from the scope of this disclosure.

In certain examples, both primary latch 210 and secondary latch 212 need to be placed in an unlock position before handle 214 may transition from a locked position to an unlocked position. When handle 214 is in the unlocked position, the handle may be utilized to remove drive carrier 202 and the corresponding cold plug device, such as cold plug device 102 in server 100 of FIG. 1, from an information handling system. The need to move or place both primary latch 210 and secondary latch 212 in the unlock position may add a level of protection to prevent a cold plug device from being removed before an information handling system is shut down.

In an example, primary latch 210 may transition between locked and unlocked positions by sliding within latch channel 220, as will be described in greater detail below. Secondary latch 212 may transition from the locked position to the unlocked position by a force being exerted on the secondary latch in the direction of the arrows on the latch, as will be described in greater detail below. After both of primary latch 210 and secondary latch 212 are placed in the unlocked position, handle 214 may transition from the locked position to the unlocked position to enable the device to be removed from the information handling system.

In an example, label 220 may be any suitable component indicating that the device is a cold plug device such that an information handling system, such as server 100 of FIG. 1, should be powered down prior to the removal of device 102 of FIG. 1. For example, label 220 may include the type of device, such as a compute express link (CXL) memory or the like.

In an example, a device, such as device 404 of FIG. 4, may be in physical communication with device carrier 202 in any suitable manner as will be described with respect to FIG. 4 below. A device and device carrier 202 may be collectively referred to as a device, such as cold plug device 102 of FIG. 1. One of ordinary skill would recognize that side and front are descriptive based on FIG. 2. However, any descriptive word or words may be utilized to describe an orientation of the portions of device carrier 202 without varying from the scope of this disclosure.

FIG. 3 illustrates drive carrier 302 according to at least one embodiment of the disclosure. Device carrier 302 includes a front portion 304, which in turn includes a primary latch 310, a secondary latch 312, a handle 314, and an extension portion 316. Handle 314 may be any suitable component such as a cam lever, which may be utilized during removal of a device from an information handling system, such as a cold plug device 102 in server 100 of FIG. 1. Handle 314 includes a latch channel 320 and a label 322. Drive carrier 302 may include additional components without varying from the scope of this disclosure.

As similarly described with respect to device carrier 202 of FIG. 2, both primary latch 310 and secondary latch 312 need to be placed in an unlock position before handle 314 may transition from a locked position to an unlocked position. When handle 314 is in the unlocked position, the handle may be utilized to remove drive carrier 302 and the corresponding cold plug device, such as cold plug device 102 in server 100 of FIG. 1, from an information handling system. The need to move or place both primary latch 310 and secondary latch 312 in the unlock position may add a level of protection to prevent a cold plug device from being removed before an information handling system is shut down.

In an example, label 322 may be any suitable component indicating that the device is a cold plug device such that an information handling system, such as server 100 of FIG. 1, should be powered down prior to the removal of device 102 of FIG. 1. For example, label 322 may include the type of device, such as a CXL memory or the like.

In an example, extension portion 316 may be in physical communication with front portion 304 of drive carrier 302. Extension portion 316 may increase the width of drive carrier 302 as compared to drive carrier 202. In an example, this increase in width of driver carrier 302 may enable the drive carrier to be inserted into a slot of an information handling system, such as server 100 of FIG. 1, that has a larger height as compared to a slot for drive carrier 202.

In an example, a device, such as device 404 of FIG. 4, may be in physical communication with device carrier 302 in any suitable manner as will be described with respect to FIG. 4 below. A device and device carrier 302 may be collectively referred to as a device, such as cold plug device 102 of FIG. 1. One of ordinary skill would recognize that side and front are descriptive based on FIG. 3. However, any descriptive word or words may be utilized to describe an orientation of the portions of device carrier 302 without varying from the scope of this disclosure.

FIG. 4 illustrates a cross-section of a portion of a system 400 including a portion of a device carrier 402 and device 404 according to at least one embodiment of the present disclosure. Device carrier 402 may be substantially similar to device carrier 202 of FIG. 2 and device carrier 302 of FIG. 3. Device carrier 402 includes a front portion 410 and side portions 412 and 414. Front portion 410 includes a handle 420, latches 422 and 424, springs 426, 428, and 430, a guide pin 432, a retention mechanism 434, and a holding component 436. In an example, spring 426 may be a torsion spring, and springs 428 and 430 may be compression springs. Handle 420 includes a latch channel 440 and a tab 442. Holding component 436 includes a spring channel 450 and a tab 452. Latch 424 includes a tab 460. System 400 may include additional components without varying from the scope of this disclosure.

In an example, a front portion of device 404 may be in physical communication with front portion 410 and side portions of the device may be in physical communication with respective side potions 412 and 414. Handle 420 is rotatably connected to a main portion of front portion 410. Additionally, spring 426 may exert a force on handle 420 to bias the handle in an unlocked position. However, tab 452 may be located within an opening of retention mechanism 434, which in turn may hold handle 420 in a locked position. Latch 422 is physically and permanently coupled to holding component 436. Based on the connection between latch 422 and holding component 436, spring 430 may bias the latch in a locked position by exerting a force on the holding component that biases tab 452 within an opening of retention mechanism 434. In an example, spring 430 may be located in between a portion of handle 420 and an internal wall of spring channel 450 of holding component 436.

In certain examples, latch 424 may transition between a locked position and an unlocked position. When latch 424 is in the locked position, tab 460 and handle 420 may be in physical communication, which in turn may hold the handle in the locked or closed position. In an example, guide pin 432 may hold spring 428 in position so that the spring may exert a force on latch 424. This force from spring 428 may bias latch 424 toward the locked position. The biasing of latch 424 toward the locked position may hold handle 420 in the locked or closed position.

In certain examples, handle 420 may be utilized to remove a device 302 and device carrier 304 from an information handling system, such as server 100 of FIG. 1. Handle 420 may transition between a locked position and a locked position. When handle 420 is in the locked position, the handle may hold device 302 within an information handling system, such as server 100 of FIG. 1. When handle 420 is in the unlocked position, an individual may exert a force on the handle to remove device 302 from within an information handling system.

FIGS. 5-7 illustrate diagrams of different components of a device carrier 502 in different positions during a transition from a locked position to an unlocked position according to at least one embodiment of the present disclosure. Device carrier 502 may be substantially similar to device carrier 402 of FIG. 4, device carrier 302 of FIG. 3, and device carrier 202 of FIG. 2. As illustrated in FIGS. 5-7, covers and other components of device carrier 502 have been removed to enable particular components to be viewed more easily. Device carrier 502 includes a handle 520, latches 522 and 524, springs 528 and 530, a retention mechanism 534, and a holding component 536. In an example, springs 528 and 530 may be compression springs. Handle 520 includes a latch channel 540 and a tab 542. Holding component 536 includes a tab 552, and latch 524 includes a tab 560. Device carrier 502 may include additional components without varying from the scope of this disclosure.

Referring now to FIG. 5, handle 520, latch 522, and latch 524 are all in their respective locked positions. As illustrated in FIG. 5, handle 520 may be held in the locked position by multiple components. For example, tab 552 may be located within the opening of retention mechanism 534. In certain examples, spring 530 may bias holding component 536 toward a position to place tab 552 within the opening of retention mechanism 534. Based on this location of tab 552, retention mechanism 534 may hold handle, via tab 552 and holding component 536, in the locked position and prevent the handle from transitioning to the unlocked position.

Additionally, handle 520 may be held in the locked position by the physical communication between tab 542 and latch 524. In an example, when latch 524 is in the locked position, a first end of the latch may be located above tab 542 so that handle 520 may not transition from the locked position to the unlocked position. The first end of latch 524 may be distal from tab 560 as shown in FIG. 5. In an example, spring 528 may bias latch 524 toward a position to place the first end of the latch above tab 542 of handle 520.

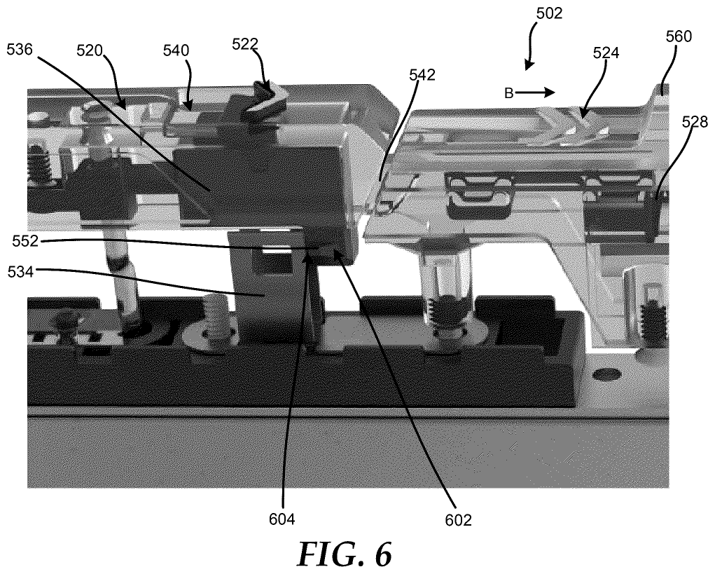

In certain examples, multiple movements need to be performed before handle 520 may transition from the locked to unlocked position. The first movement may include a force being exerted on latch 522 in the direction of arrow A. Based on this force, latch 522 may slide from one end of channel 540 (the locked position of latch 522) to the other end of the channel (the unlocked position of latch 522. As latch 522 moves from the locked position to the unlocked position within channel 540, tab 552 of holding component 536 may slide out of the opening of retention mechanism 534 as shown in FIG. 6.

Referring now to FIG. 6, tab 522 may include a ramp portion 602 and a catch portion 604. In an example, latch 522 and holding component 536 are securely mounted or connected together, such that the movement of the latch will move the holding component and movement of the holding component will move the latch. Based on the force being exerted on latch 522 in the direction of arrow A as shown in FIG. 5, latch 522 may slide along channel 540 and a section of retention mechanism 534 may slide along ramp portion 602 of tab 522. In certain examples, a section of holding component 536 may flex away from retention mechanism 534 as the retention mechanism 534 slides along ramp portion 602.

When latch 522 has moved from the first end of channel 540 to the other end of the channel, tab 552 of holding component 536 may slide out of the opening of retention mechanism 534 and catch portion 604 of tab 552 may snap beyond an edge of the retention mechanism as illustrated in FIG. 6. In response to catch portion 604 of tab 552 being located beyond retention mechanism 534, the catch portion may hold latch 522 in the unlocked position. In an example, catch portion 604 may prevent tab 552 from sliding back within the opening of retention mechanism 534.

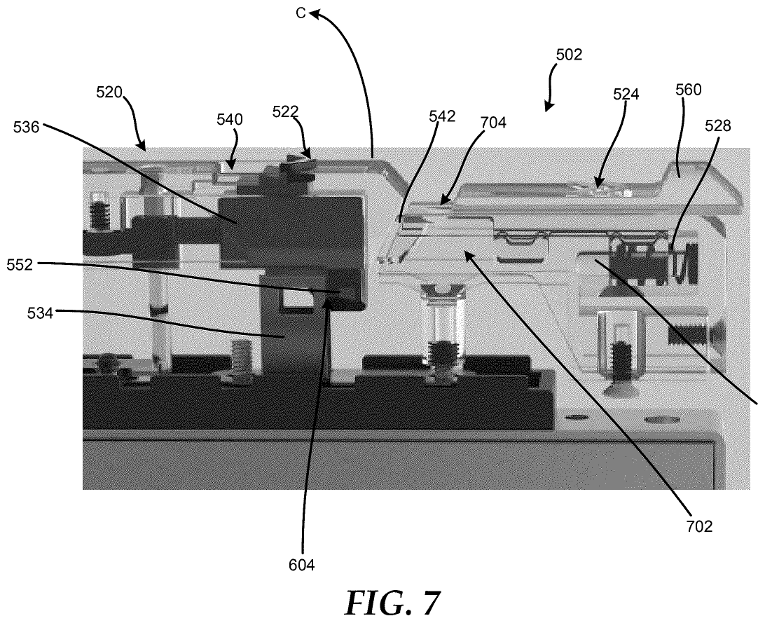

In certain examples, spring 528 may exert a force on latch 524 to bias the latch towards the locked position. In this example, the force of spring 528 may prevent latch 524 from accidentally transitioning from the locked position to the unlocked position, which in turn may hold tab 542 of handle 520 below the latch. After latch 522 is placed in the unlocked position, a force may be exerted on tab 560 of latch 524 in the direction of arrow B, which in turn may cause latch 524 to transition from the locked position to the unlocked position. In an example, the force exerted on tab 560, in the direction of arrow B, may be greater than the force exerted on latch 524 to enable the transition of the latch to the unlocked position. When both latches 522 and 524 are in the unlocked position, handle 520 may automatically transition to the unlocked position as will be described with respect to FIG. 7.

Referring now to FIG. 7, device carrier 502 may further include a guide component 702 which includes a slot 704. As shown in FIG. 7, tab 542 of handle 520 may be located within slot 704 of guide component 702. Additionally, latch 524 may be coupled to guide component 702, but the latch may be able to slide along the guide component to transition from a locked position to an unlocked position. In an example, spring 528 may exert a force on latch 524 to bias the latch towards the locked position. In this example, the force of spring 528 may prevent latch 524 from accidentally transitioning from the locked position to the unlocked position, which in turn may hold tab 542 of handle 520 within slot 704 of guide component 702.

As illustrated in FIG. 7, catch portion 604 of tab 552 may continue to hold latch 522 in the unlocked position. When latch 524 is in the unlocked position, the end of the latch that is opposite of tab 560 may no longer be located above tab 552 of handle 520. In response to latch 522 not holding tab 552 within slot 704, a spring connected to handle 520 may automatically cause the handle to transition from the locked position to the unlocked position. For example, the force of a spring, such as spring 426 of FIG. 4, may cause handle 520 to rotate in the direction of arrow C. As handle 520 rotates in the direction of arrow C, the handle transitions from the locked position to the unlocked position.

When handle 520 is in the unlocked position, a force may be exerted on the handle to remove a device from an information handling system, such as a cold plug device 102 in server 100 of FIG. 1. In an example, after handle 520 is in the unlocked position, the force on tab 560 of latch 524 may be removed and spring 528 may automatically bias the latch towards the locked position. Additionally, when handle 520 is in the unlocked position, catch portion 604 may no longer be in physical communication with retention mechanism 534, such that spring 530, shown in FIG. 5, may automatically bias latch 522 back towards the locked position.

In certain examples, if device carrier 502 may be placed back in an initial position based on a force being exerted on handle 520 in a direction that is substantially opposite of arrow C. As handle 520 is pushed downward, an angled portion of tab 542 may interface within an angled portion of latch 524 to enable the tab to snap beyond the end of latch 524 and be held within slot 704 of guide component 702. Similarly, as handle 520 is pushed downward, an angled portion of tab 552 may interface within retention mechanism 534 to enable the tab to snap fit within the opening of the retention mechanism. Based on tab 552 being within the opening of retention mechanism 534 and latch 524 holding tab 542 within slot 704, handle 520 is securely held in the locked position as illustrated in FIG. 5.

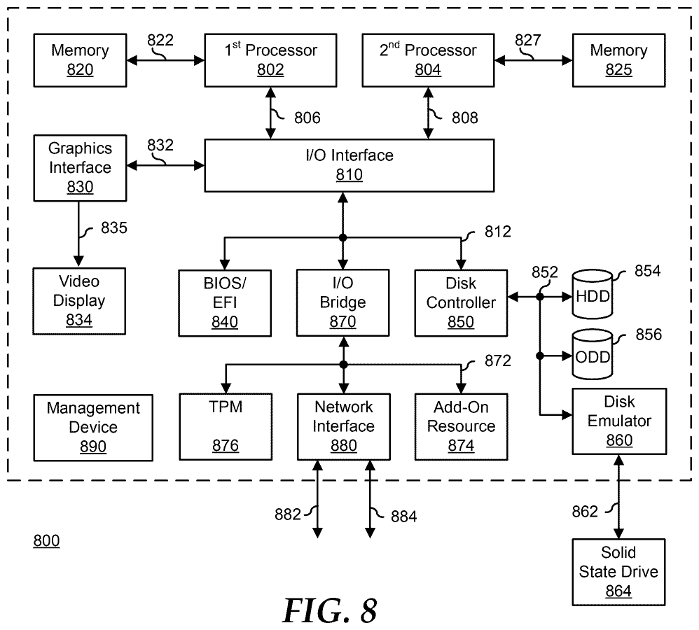

FIG. 8 shows a generalized embodiment of an information handling system 800 according to an embodiment of the present disclosure. Information handling system 800 may be substantially similar to information handling system 100 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 800 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 800 can include processing resources for executing machine-executable code, such as a central processing unit (CPU), a programmable logic array (PLA), an embedded device such as a System-on-a-Chip (SoC), or other control logic hardware. Information handling system 800 can also include one or more computer-readable medium for storing machine-executable code, such as software or data. Additional components of information handling system 800 can include one or more storage devices that can store machine-executable code, one or more communications ports for communicating with external devices, and various input and output (I/O) devices, such as a keyboard, a mouse, and a video display. Information handling system 800 can also include one or more buses operable to transmit information between the various hardware components.

Information handling system 800 can include devices or modules that embody one or more of the devices or modules described below and operates to perform one or more of the methods described below. Information handling system 800 includes a processors 802 and 804, an input/output (I/O) interface 810, memories 820 and 825, a graphics interface 830, a basic input and output system/universal extensible firmware interface (BIOS/UEFI) module 840, a disk controller 850, a hard disk drive (HDD) 854, an optical disk drive (ODD) 856, a disk emulator 860 connected to an external solid state drive (SSD) 864, an I/O bridge 870, one or more add-on resources 874, a trusted platform module (TPM) 876, a network interface 880, a management device 890, and a power supply 895. Processors 802 and 804, I/O interface 810, memory 820, graphics interface 830, BIOS/UEFI module 840, disk controller 850, HDD 854, ODD 856, disk emulator 860, SSD 864, I/O bridge 870, add-on resources 874, TPM 876, and network interface 880 operate together to provide a host environment of information handling system 800 that operates to provide the data processing functionality of the information handling system. The host environment operates to execute machine-executable code, including platform BIOS/UEFI code, device firmware, operating system code, applications, programs, and the like, to perform the data processing tasks associated with information handling system 800.

In the host environment, processor 802 is connected to I/O interface 810 via processor interface 806, and processor 804 is connected to the I/O interface via processor interface 808. Memory 820 is connected to processor 802 via a memory interface 822. Memory 825 is connected to processor 804 via a memory interface 827. Graphics interface 830 is connected to I/O interface 810 via a graphics interface 832 and provides a video display output 836 to a video display 834. In a particular embodiment, information handling system 800 includes separate memories that are dedicated to each of processors 802 and 804 via separate memory interfaces. An example of memories 820 and 830 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 840, disk controller 850, and I/O bridge 870 are connected to I/O interface 810 via an I/O channel 812. An example of I/O channel 812 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 810 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 840 includes BIOS/UEFI code operable to detect resources within information handling system 800, to provide drivers for the resources, initialize the resources, and access the resources. BIOS/UEFI module 840 includes code that operates to detect resources within information handling system 800, to provide drivers for the resources, to initialize the resources, and to access the resources.

Disk controller 850 includes a disk interface 852 that connects the disk controller to HDD 854, to ODD 856, and to disk emulator 860. An example of disk interface 852 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 860 permits SSD 864 to be connected to information handling system 800 via an external interface 862. An example of external interface 862 includes a USB interface, an IEEE 4394 (Firewire) interface, a proprietary interface, or a combination thereof. Alternatively, solid-state drive 864 can be disposed within information handling system 800.

I/O bridge 870 includes a peripheral interface 872 that connects the I/O bridge to add-on resource 874, to TPM 876, and to network interface 880. Peripheral interface 872 can be the same type of interface as I/O channel 812 or can be a different type of interface. As such, I/O bridge 870 extends the capacity of I/O channel 812 when peripheral interface 872 and the I/O channel are of the same type, and the I/O bridge translates information from a format suitable to the I/O channel to a format suitable to the peripheral channel 872 when they are of a different type. Add-on resource 874 can include a data storage system, an additional graphics interface, a network interface card (NIC), a sound/video processing card, another add-on resource, or a combination thereof. Add-on resource 874 can be on a main circuit board, on separate circuit board or add-in card disposed within information handling system 800, a device that is external to the information handling system, or a combination thereof.

Network interface 880 represents a NIC disposed within information handling system 800, on a main circuit board of the information handling system, integrated onto another component such as I/O interface 810, in another suitable location, or a combination thereof. Network interface device 880 includes network channels 882 and 884 that provide interfaces to devices that are external to information handling system 800. In a particular embodiment, network channels 882 and 884 are of a different type than peripheral channel 872 and network interface 880 translates information from a format suitable to the peripheral channel to a format suitable to external devices. An example of network channels 882 and 884 includes InfiniBand channels, Fibre Channel channels, Gigabit Ethernet channels, proprietary channel architectures, or a combination thereof. Network channels 882 and 884 can be connected to external network resources (not illustrated). The network resource can include another information handling system, a data storage system, another network, a grid management system, another suitable resource, or a combination thereof.

Management device 890 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 800. In particular, management device 890 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 800, such as system cooling fans and power supplies. Management device 890 can include a network connection to an external management system, and the management device can communicate with the management system to report status information for information handling system 800, to receive BIOS/UEFI or system firmware updates, or to perform other task for managing and controlling the operation of information handling system 800.

Management device 890 can operate off of a separate power plane from the components of the host environment so that the management device receives power to manage information handling system 800 when the information handling system is otherwise shut down. An example of management device 890 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 890 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A drive carrier for a device of an information handling system, the drive carrier comprising:
a front portion to be placed in physical communication with the device, wherein the device is a cold plug device to be inserted within a server, the front portion including:
a handle rotatable between a locked position and an unlocked position;
a first latch in physical communication with the handle, the first latch configured to slide between a first position and a second position, wherein the handle is held in the locked position when the first latch is in the first position; and
a second latch configured to slide between a third position and a fourth position, a first end of the second latch in physical communication with a portion of the first latch when the second latch is in the third position, wherein the handle transitions from the locked position to the unlocked position when both the first latch is in the second position and the second latch is in the fourth position.

2. The drive carrier of claim 1, further comprising: a first spring to bias the second latch towards the third position.

3. The drive carrier of claim 2, further comprising: a second spring to bias the first latch towards the first position.

4. The drive carrier of claim 1, wherein the first latch includes a lock tab to secure the first latch in the first position.

5. The drive carrier of claim 4, wherein the first latch transitions from the first position to the second position in response to the first forced exerted being greater than a second force of the second spring.

6. The drive carrier of claim 4, further comprising: a retention mechanism permanently mounted within the drive carrier, the retention mechanism including a component to receive the lock tab when the first latch is in the first position.

7. The drive carrier of claim 6, wherein the lock tab holds the first latch in the first position when the lock tab is located within the component of the retention mechanism.

8. The drive carrier of claim 1, wherein the handle includes a label indicating that the device is the cold plug device.

9. An information handling system comprising:
a bay including a plurality of slots;
a device to be inserted within one of the slots of the bay, wherein the device is a cold plug device to be inserted within the information handling system; and
a device carrier to be in physical communication with the device, the device carrier including:
a front portion to be placed in physical communication with a front portion of the device, the front portion including:
a handle rotatable between a locked position and an unlocked position;
a first latch in physical communication with the handle, the first latch configured to slide between a first position and a second position, wherein the handle is held in the locked position when the first latch is in the first position; and
a second latch configured to slide between a third position and a fourth position, a first end of the second latch in physical communication with a portion of the first latch when the second latch is in the third position, wherein the handle transitions from the locked position to the unlocked position when both the first latch in the second position and the second latch is in the fourth position.

10. The information handling system of claim 9, wherein the drive carrier further includes: a first spring to bias the second latch towards the third position.

11. The information handling system of claim 10, wherein the drive carrier further includes: a second spring to bias the first latch towards the first position.

12. The information handling system of claim 9, wherein the first latch includes a lock tab to secure the first latch in the first position.

13. The information handling system of claim 12, wherein the first latch transitions from the first position to the second position in response to the first forced exerted being greater than a second force of the second spring.

14. The information handling system of claim 12, wherein the drive carrier further includes: a retention mechanism permanently mounted within the drive carrier, the retention mechanism including a component to receive the lock tab when the first latch is in the first position.

15. The information handling system of claim 14, wherein the lock tab holds the first latch in the first position when the lock tab is located within the component of the retention mechanism.

16. The information handling system of claim 9, wherein the handle includes a label indicating that the device is the cold plug device.

17. A drive carrier for a device of an information handling system, the drive carrier comprising:
a front portion to be placed in physical communication with the device, wherein the device is a cold plug device to be inserted within a server, the front portion including:
a handle rotatable between a locked position and an unlocked position;
a first latch in physical communication with the handle, the first latch configured to slide between a first position and a second position, wherein the handle is held in the locked position when the first latch is in the first position;
a first spring to bias the first latch towards the first position, wherein the first latch transitions from the first position to the second position in response to the first forced exerted being greater than a second force of the first spring; and
a second latch configured to slide between a third position and a fourth position, a first end of the second latch in physical communication with a portion of the first latch when the second latch is in the third position, wherein the handle transitions from the locked position to the unlocked position when both the first latch in the second position and the second latch is in the fourth position.

18. The drive carrier of claim 17, further comprising: a second spring to bias the second latch towards the third position.

19. The drive carrier of claim 17, wherein the first latch includes a lock tab to secure the first latch in the first position.

20. The drive carrier of claim 19, further comprising: a retention mechanism permanently mounted within the drive carrier, the retention mechanism including a component to receive the lock tab when the first latch is in the first position.
